(19) United States
(12) Patent Application Publication
(10) Pub. No.: US 2024/0079328 A1
(43) Pub. Date: Mar. 7, 2024

(54) SEMICONDUCTOR DEVICE

(71) Applicant: SAMSUNG ELECTRONICS CO., LTD., Suwon-si (KR)

(72) Inventors: Taejun YOO, Suwon-si (KR); Changbeom KIM, Suwon-si (KR); Taejung SEOL, Suwon-si (KR)

(73) Assignee: SAMSUNG ELECTRONICS CO., LTD., Suwon-si (KR)

(21) Appl. No.: 18/133,198

(22) Filed: Apr. 11, 2023

(30) Foreign Application Priority Data
Sep. 2, 2022 (KR) 10-2022-0111628

(51) Int. Cl. H01L 23/528; H01L 27/092; H01L 29/06; H01L 29/423; H01L 29/775

(52) U.S. Cl. CPC H01L 23/5286; H01L 27/092; H01L 29/0673; H01L 29/42392; H01L 29/775

(57) ABSTRACT

A semiconductor device includes a logic cell region on a substrate, an interconnection layer on the logic cell region, the interconnection layer including a plurality of metal layers on the logic cell region, and a first vertical structure in the interconnection layer, where the first vertical structure vertically connects the logic cell region to an uppermost metal layer of the plurality of metal layers, each of the plurality of unit structures includes a lower via, a lower interconnection line, an upper via, and an upper interconnection line, the lower interconnection line and the upper interconnection line of each respective unit structure of the plurality of unit structures cross each other, and the upper interconnection line of each of the plurality of unit structures includes a first upper interconnection line.

### CROSS-REFERENCE TO RELATED APPLICATION(S)

This application is based on and claims priority to Korean Patent Application No. 10-2022-0111628, filed on Sep. 2, 2022, in the Korean Intellectual Property Office, the disclosure of which is incorporated herein by reference in its entirety.

### BACKGROUND

### 1. Field

Example embodiments of the disclosure relate to a semiconductor device, and in particular, to a semiconductor device including a field effect transistor.

### 2. Description of Related Art

Due to their small-sized, multifunctional, and/or low-cost characteristics, semiconductor devices are being esteemed as important elements in the electronics industry. The semiconductor devices may be classified into a semiconductor memory device for storing data, a semiconductor logic device for processing data, and a hybrid semiconductor device including both of memory and logic elements. As the electronic industry advances, there is an increasing demand for semiconductor devices with improved characteristics. For example, there is an increasing demand for semiconductor devices with high reliability, high performance, and/or multiple functions. To meet this demand, structural complexity and/or integration density of semiconductor devices are being increased.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved electrical and reliability characteristics.

Additional aspects will be set forth in part in the description which follows and, in part, will be apparent from the description, or may be learned by practice of the presented embodiments.

According to an aspect of an example embodiment, a semiconductor device may include a logic cell region on a substrate, an interconnection layer on the logic cell region, the interconnection layer including a plurality of metal layers on the logic cell region, and a first vertical structure in the interconnection layer, where the first vertical structure vertically connects the logic cell region to an uppermost metal layer of the plurality of metal layers, each of the plurality of unit structures includes a lower via, a lower interconnection line, an upper via, and an upper interconnection line, the lower interconnection line and the upper interconnection line of each respective unit structure of the plurality of unit structures cross each other, the upper interconnection line of each of the plurality of unit structures includes a first upper interconnection line, and wherein the upper interconnection line for each of the plurality of unit structures except for an uppermost unit structure of the plurality of unit structures includes a second upper interconnection line adjacent to the first upper interconnection line.

According to an aspect of an example embodiment, a semiconductor device may include a logic cell region on a substrate, an interconnection layer on the logic cell region, the interconnection layer including a plurality of metal layers on the logic cell region, and a first vertical structure and a second vertical structure in the interconnection layer, where the first vertical structure and the second vertical structure vertically connect the logic cell region to an n-th metal layer in an uppermost metal layer of the plurality of metal layers, where n is an from 9 to 15, each of the first vertical structure and the second vertical structure includes alternately stacked lower interconnection lines and upper interconnection lines, the lower interconnection lines and the upper interconnection lines of each respective vertical structure cross each other, and the first vertical structure further includes at least one layer between the logic cell region and the n-th metal layer, electrically connecting the logic cell region and the n-th metal layer.

According to an aspect of an example embodiment, a semiconductor device may include a logic cell region on a substrate, an interconnection layer on the logic cell region, the interconnection layer including a plurality of metal layers on the logic cell region and a large metal layer on an n-th metal layer, where the large metal layer being a largest metal layer among the plurality of metal layers and where the large metal layer is an uppermost metal layer of the plurality of metal layers, and a first vertical structure and a second vertical structure in the interconnection layer, where the first vertical structure and the second vertical structure vertically connect the logic cell region and the large metal layer, the first vertical structure is configured to provide a first current path and a second current path which vertically extend from the logic cell region, the first current path and the second current path are merged in an interconnection line of an (n−2)-th metal layer, forming a first merged current path connected to the largest metal layer, the third current path and the fourth current path are merged in an interconnection line of the n-th metal layer, forming a second merged current path connected to the largest metal layer, and n is an integer from 9 to 15.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a semiconductor device according to an embodiment of the disclosure;

FIG. 2 is a cross-sectional view illustrating a semiconductor device according to a comparative example;

FIG. 3 is a cross-sectional view taken along the line A-A′ of FIG. 1 illustrating a semiconductor device according to an embodiment of the disclosure;

FIG. 4 is a diagram illustrating a semiconductor device according to an embodiment of the disclosure;

FIG. 5 is a diagram illustrating a semiconductor device according to an embodiment of the disclosure;

FIG. 6 is a cross-sectional view illustrating a semiconductor device according to a comparative example of the disclosure;

FIG. 7 is a sectional view taken along the line A-A′ of FIG. 5 illustrating a semiconductor device according to an embodiment of the disclosure;

FIG. 8 is a diagram illustrating a logic cell region according to an embodiment of the disclosure;

FIG. 9 is a diagram illustrating a portion ‘M’ of FIG. 8 according to an embodiment of the disclosure;

FIGS. 10A, 10B, 10C and 10D are cross-sectional views, which are respectively taken along lines A-A′, B-B′, C-C′, and D-D′ of FIG. 9, according to an embodiment of the disclosure; and

FIG. 11 is a diagram illustrating a logic cell region according to an embodiment of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

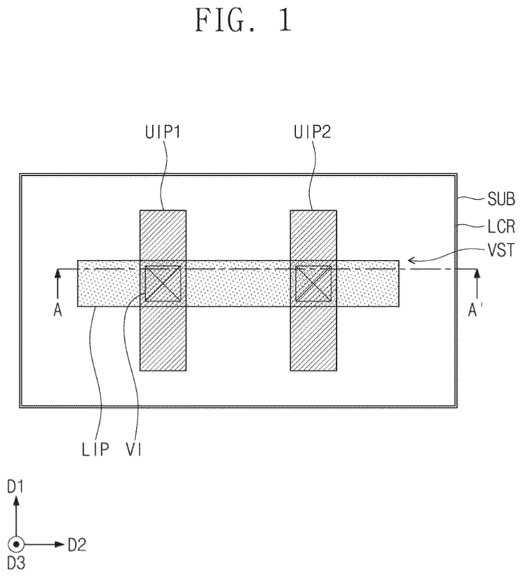

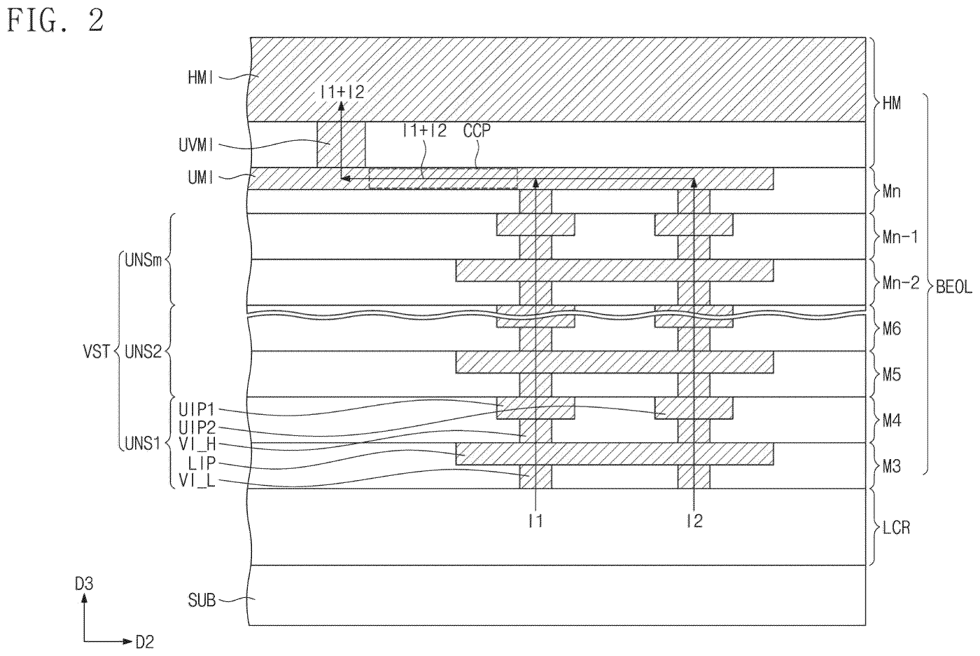

FIG. 1 is a diagram illustrating a semiconductor device according to an embodiment of the disclosure. FIG. 2 is a cross-sectional view illustrating a semiconductor device according to a comparative example. That is, FIG. 2 shows a comparative example that may share a structure of the semiconductor device of FIG. 1 in the view of FIG. 1, but includes a cross-section of components that differs from example embodiments disclosed herein.

Referring to FIGS. 1 and 2, a logic cell region LCR may be provided on a substrate SUB. The substrate SUB may be a semiconductor substrate that is formed of or includes silicon, germanium, silicon germanium, a compound semiconductor material, or the like. As an example, the substrate SUB may be a silicon wafer.

A front-end-of-line (FEOL) layer may be provided on the substrate SUB. For example, the logic cell region LCR may be provided on the substrate SUB. Logic transistors constituting a logic circuit may be disposed in the logic cell region LCR. The logic cell region LCR or a logic cell may include a logic device or circuit (e.g., AND, OR, XOR, XNOR, inverter, and so forth), which is configured to execute a specific function. That is, the logic cell region LCR or the logic cell may include transistors, which constitute a logic device, and interconnection lines, which connect the transistors to each other.

A vertical structure VST may be provided on the logic cell region LCR. The vertical structure VST may be provided in a back-end-of-line (BEOL) layer (e.g., an interconnection layer BEOL) on the logic cell region LCR.

The vertical structure VST may include a plurality of unit structures UNS1, UNS2, . . . , and UNSm which are stacked on the substrate SUB. For example, the vertical structure VST may be vertically extended from a third metal layer M3 of the interconnection layer BEOL to an n-th metal layer Mn.

Each of the unit structures UNS1, UNS2, . . . , and UNSm may include a lower interconnection line LIP and upper interconnection lines UIP1 and UIP2. When viewed in a plan view, the lower interconnection line LIP and the upper interconnection lines UIP1 and UIP2 may cross each other and have a cross or mesh shape.

Each of the unit structures UNS1, UNS2, . . . , and UNSm may include a via VI. The via VI may include a lower via VI_L, which may be provided below the lower interconnection line LIP, and an upper via VI_H, which may be provided below the upper interconnection line UIP1 or UIP2. The upper via VI_H may be disposed at an intersection of the lower interconnection line LIP and the upper interconnection line UIP1 or UIP2. The lower via VI_L may vertically overlap the upper via VI_H.

As an example, each of the unit structures UNS1, UNS2, . . . , and UNSm may include a lower interconnection line LIP, a first upper interconnection line UIP1, and a second upper interconnection line UIP2. The lower interconnection line LIP may be a line-shaped pattern or bar-shaped pattern that extends in a second direction D2. Each of the first and second upper interconnection lines UIP1 and UIP2 may be a line-shaped pattern or bar-shaped pattern that extends in a first direction D1.

The vertical structure VST may include a first unit structure UNS1, a second unit structure UNS2, . . . , a m-th unit structure UNSm, which are sequentially stacked, where m is an integer from 3 to 6. The first unit structure UNS1 may be the lowermost unit structure of the vertical structure VST, and the m-th unit structure UNSm may be the uppermost unit structure of the vertical structure VST.

As shown in FIG. 2, the interconnection layer BEOL may include a third metal layer M3, a fourth metal layer M4, a fifth metal layer M5, a sixth metal layer M6, . . . , an (n−2)-th metal layer Mn−2, an (n−1)-th metal layer Mn−1, an n-th metal layer Mn, and a largest metal layer HM of the metal layers, which are sequentially stacked, where n is an integer from 9 to 15.

For example, the lower interconnection line LIP of the first unit structure UNS1 may be an interconnection line of the third metal layer M3, and the upper interconnection lines UIP1 and UIP2 may be interconnection lines of the fourth metal layer M4. The lower interconnection line LIP of the m-th unit structure UNSm may be an interconnection line of the (n−2)-th metal layer Mn−2, and the upper interconnection lines UIP1 and UIP2 may be interconnection lines of the (n−1)-th metal layer Mn−1.

The vertical structure VST may extend from the logic cell region LCR to a connection line UMI of the n-th metal layer Mn in a vertical direction (i.e., a third direction D3). As an example, signals may be exchanged between the logic cell region LCR and the connection line UMI through the vertical structure VST. As another example, electric power may be delivered between the logic cell region LCR and the connection line UMI through the vertical structure VST. The connection line UMI may be electrically connected to a largest interconnection line HMI of the largest metal layer HM through a connection via UMVI.

A first current I1 and a second current I2 may flow from the logic cell region LCR to the connection line UMI through separate current paths which are constructed in the vertical structure VST. The first current I1 may be conducted to the connection line UMI through the first upper interconnection lines UIP1 of the stacked unit structures UNS1, UNS2, . . . , and UNSm. The second current I2 may be conducted to the connection line UMI through the second upper interconnection lines UIP2 of the stacked unit structures UNS1, UNS2, . . . , and UNSm.

The first current I1 and the second current I2 may be merged in the connection line UMI. The first and second currents I1+I2, which are merged in the connection line UMI, may be conducted to the largest interconnection line HMI through a connection region CCP of the connection line UMI and the connection via UMVI.

According to the comparative example of FIG. 2, the first current I1 and the second current I2 may be conducted along different current paths until they are merged in the connection line UMI. The merged current I1+I2 may pass through the connection region CCP of the connection line UMI. In this case, an amount of the current passing through the connection region CCP of the connection line UMI may be excessively large, and this may lead to low stability of the connection line UMI. Furthermore, since the connection line UMI is smaller than the largest interconnection line HMI, the connection line UMI may have a relatively high resistance, and in this case, it may be problematic to conduct the merged current I1+I2 through the connection region CCP. As a result, the interconnection structure according to the comparative example may lead to deterioration in electrical and reliability characteristics of the semiconductor device.

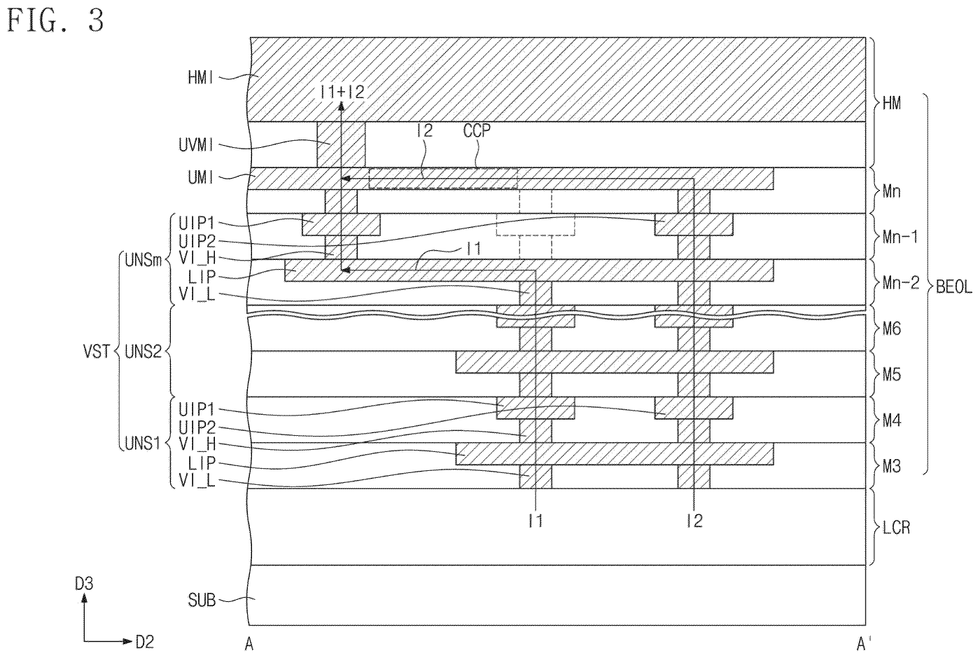

FIG. 3 is a cross-sectional view taken along the line A-A′ of FIG. 1 illustrating a semiconductor device according to an embodiment of the disclosure.

Referring to FIGS. 1 and 3, the m-th unit structure UNSm of the vertical structure VST may have a different shape from other unit structures (e.g., UNS1, UNS2, . . . ) placed thereunder. For example, the m-th unit structure UNSm may have an asymmetric structure.

In the underlying unit structures (e.g., UNS1, UNS2, . . . ) below the m-th unit structure UNSm, the first upper interconnection lines UIP1 may be stacked and overlap each other. In an embodiment, an upper interconnection line, which overlaps the first upper interconnection lines UIP1, may be omitted from the m-th unit structure UNSm. In another embodiment, the upper via VI_H, which overlaps the first upper interconnection lines UIP1, may be omitted from the m-th unit structure UNSm.

According to example embodiments, the first upper interconnection line UIP1 and the upper via VI_H in the m-th unit structure UNSm may be moved such that they are located at positions vertically overlapping the connection via UMVI. Due to the change of the positions of the first upper interconnection line UIP1 and the upper via VI_H, the lower interconnection line LIP may have a horizontally-extended shape, compared with that in the underlying unit structure.

In example embodiments, the first current I1 and the second current I2 may not be merged in the connection line UMI and may be conducted through separate current paths, as illustrated in FIG. 3. For example, the connection region CCP of the connection line UMI may be used as a current path for only the second current I2. The first current I1 and the second current I2 may be merged in the connection via UMVI and may be conducted to the largest interconnection line HMI.

As shown in FIG. 3, since the connection region CCP of the connection line UMI is used as the current path for only the second current I2, the stability of the connection line UMI may be improved, unlike the comparative example described with reference to FIG. 2. Furthermore, the second current I2 may effectively pass through the connection region CCP without a current crowding problem. As a result, the interconnection structure according to example embodiments may contribute to improve the electrical and reliability characteristics of the semiconductor device.

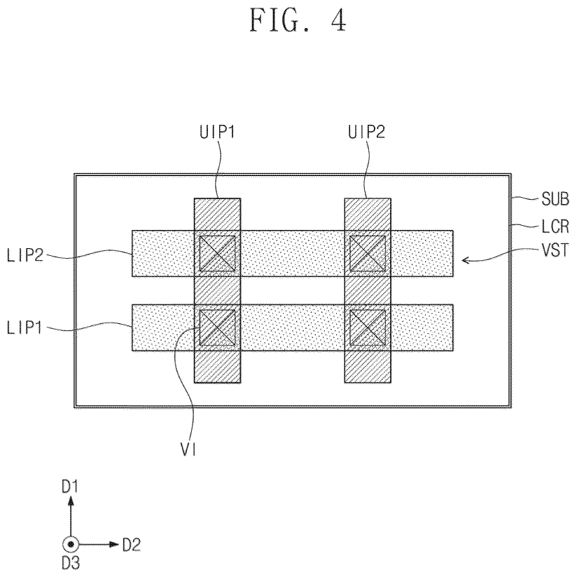

FIG. 4 is a diagram illustrating a semiconductor device according to an embodiment of the disclosure. Referring to FIG. 4, the vertical structure VST may include first and second lower interconnection lines LIP1 and LIP2 and first and second upper interconnection lines UIP1 and UIP2. When viewed in a plan view, the first and second lower interconnection lines LIP1 and LIP2 and the first and second upper interconnection lines UIP1 and UIP2 may be provided to form a shape of mesh or pound key.

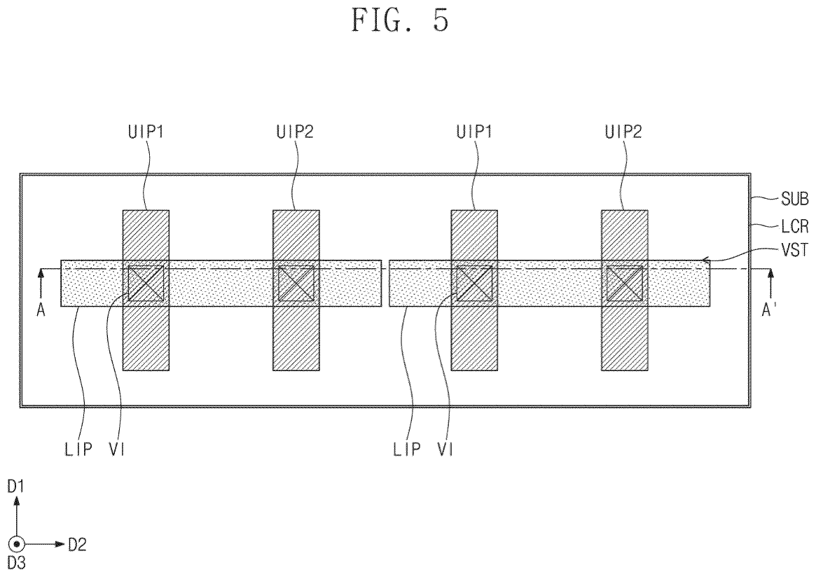

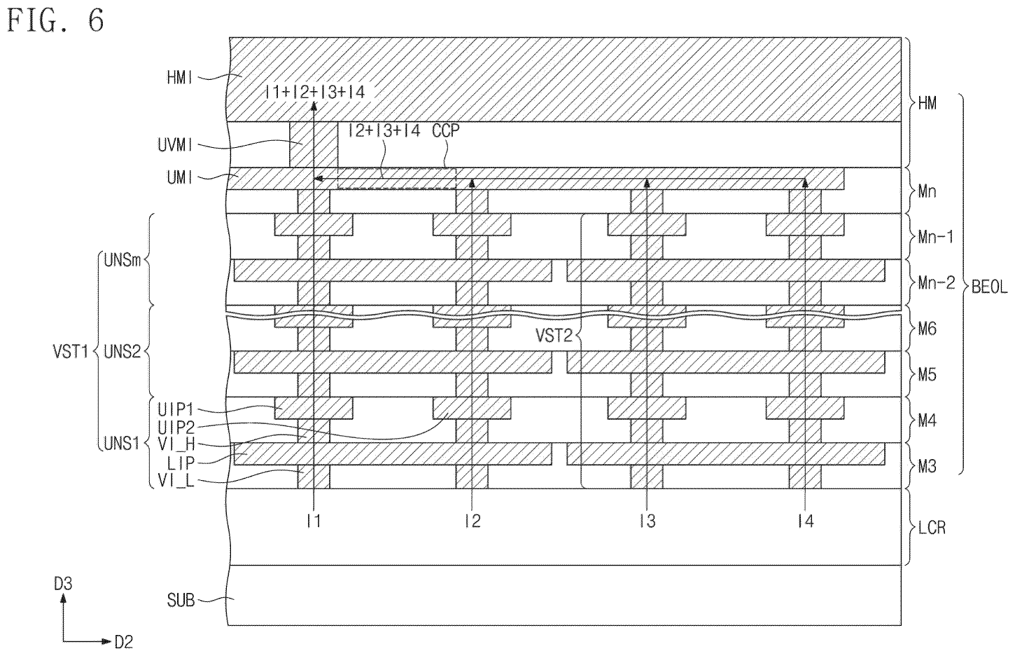

FIG. 5 is a diagram illustrating a semiconductor device according to an embodiment of the disclosure. FIG. 6 is a cross-sectional view illustrating a semiconductor device according to a comparative example of the disclosure. That is, FIG. 6 shows a comparative example that may share a structure of the semiconductor device of FIG. 5 in the view of FIG. 5, but includes a cross-section of components that differs from example embodiments disclosed herein.

A first vertical structure VST1 and a second vertical structure VST2 may be provided on the logic cell region LCR. The first vertical structure VST1 and the second vertical structure VST2 may be arranged in parallel with each other in the second direction D2. Each of the first and second vertical structures VST1 and VST2 may include the stacked unit structures UNS1, UNS2, . . . , and UNSm described above.

The first and second vertical structures VST1 and VST2 may extend from the logic cell region LCR to the connection line UMI of the n-th metal layer Mn in the third direction D3. The first current I1 and the second current I2 may be conducted from the logic cell region LCR to the connection line UMI through separate current paths which are constructed in the first vertical structure VST1. A third current I3 and a fourth current I4 may also be conducted from the logic cell region LCR to the connection line UMI through separate current paths which are constructed in the second vertical structure VST2.

The second current I2, the third current I3, and the fourth current I4 may be merged in the connection line UMI to form a single current flow. The second, third, and fourth currents I2+I3+I4, which are merged in the connection line UMI, may be conducted to the connection via UMVI through the connection region CCP. The first to fourth currents I1+I2+I3+I4 may be merged in the connection via UMVI and then may be conducted to the largest interconnection line HMI.

As shown in FIG. 6, the second current I2, the third current I3, and the fourth current I4 may be conducted along different current paths until they are merged in the connection line UMI. However, the merged current I2+I3+I4 may pass through the connection region CCP of the connection line UMI. In this case, an amount of the current passing through the connection region CCP of the connection line UMI may be excessively large, and this may lead to low stability of the connection line UMI. Furthermore, since the connection line UMI is smaller than the largest interconnection line HMI, the connection line UMI may have a relatively high resistance, and in this case, it may be problematic to conduct the merged current I2+I3+I4 through the connection region CCP. As a result, the interconnection structure according to the comparative example may lead to deterioration in electrical and reliability characteristics of the semiconductor device.

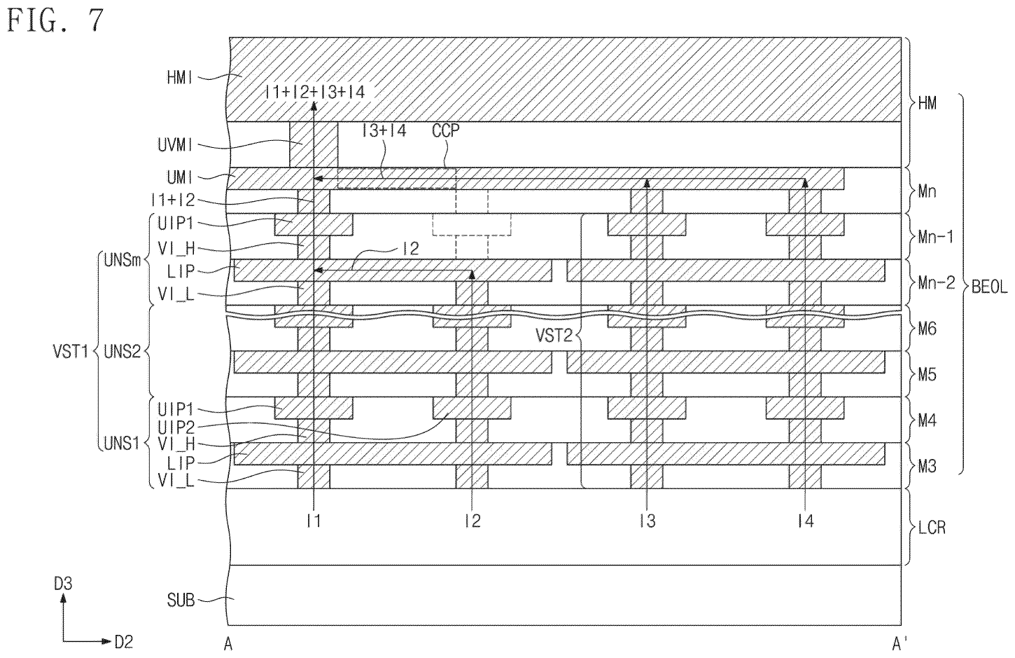

FIG. 7 is a sectional view taken along the line A-A′ of FIG. 5 illustrating a semiconductor device according to an embodiment of the disclosure.

Referring to FIGS. 5 and 7, the m-th unit structure UNSm of the first vertical structure VST1 may have a different shape from other unit structures (e.g., UNS1, UNS2, . . . ) placed thereunder. For example, the m-th unit structure UNSm may have an asymmetric structure.

In the underlying unit structures (e.g., UNS1, UNS2, . . . ) below the m-th unit structure UNSm, the second upper interconnection lines UIP2 may be stacked to overlap each other. In an embodiment, an upper interconnection line, which overlaps the second upper interconnection lines UIP2, may be omitted from the m-th unit structure UNSm. In another embodiment, the upper via VI_H, which overlaps the second upper interconnection lines UIP2, may be omitted from the m-th unit structure UNSm.

According to example embodiments, at least one of the second upper interconnection line UIP2 of the m-th unit structure UNSm and the upper via VI_H thereunder may be omitted. Only the first upper interconnection line UIP1, which vertically overlaps the connection via UMVI, and the upper via VI_H thereunder may be left in the m-th unit structure UNSm. Since at least one of the second upper interconnection line UIP2 and the upper via VI_H is omitted, the second current I2 may be merged with the first current I1 in the lower interconnection line LIP of the m-th unit structure UNSm. In other words, the second current I2 may be conducted through the interconnection line of the (n−2)-th metal layer Mn−2, not through the interconnection line of the n-th metal layer Mn.

In example embodiments, as illustrated in FIG. 7, the second current I2 may not be merged with the third and fourth currents I3+I4, in the connection line UMI. The second current I2 may be conducted through a current path different from that for the third and fourth currents I3+I4. For example, the connection region CCP of the connection line UMI may be used as a current path for only the third and fourth currents I3+I4. The first and second currents I1+I2 and the third and fourth currents I3+I4 may be merged in the connection via UMVI and then may be conducted to the largest interconnection line HMI.

As shown in FIG. 7, since, unlike the comparative example described with reference to FIG. 6, the connection region CCP of the connection line UMI may be used as a current path for only the third and fourth currents I3+I4, the stability of the connection line UMI may be improved. Furthermore, the merged current I3+I4 may effectively pass through the connection region CCP without a current crowding problem.

According to an embodiment of the disclosure, the vertical structure VST may be configured to provide at least two separate current paths, one of which may include the interconnection line of the n-th metal layer Mn, and another one of which may include the interconnection line of the (n−2)-th metal layer Mn−2. Accordingly, the semiconductor devices disclosed herein may relieve the current crowding issue in the interconnection line of the n-th metal layer Mn and to realize an effective current flow. That is, in the case where the uppermost unit structure UNSm of the vertical structure VST is provided to have the afore-described asymmetric structure, the semiconductor devices disclosed herein may improve electrical and reliability characteristics of the device.

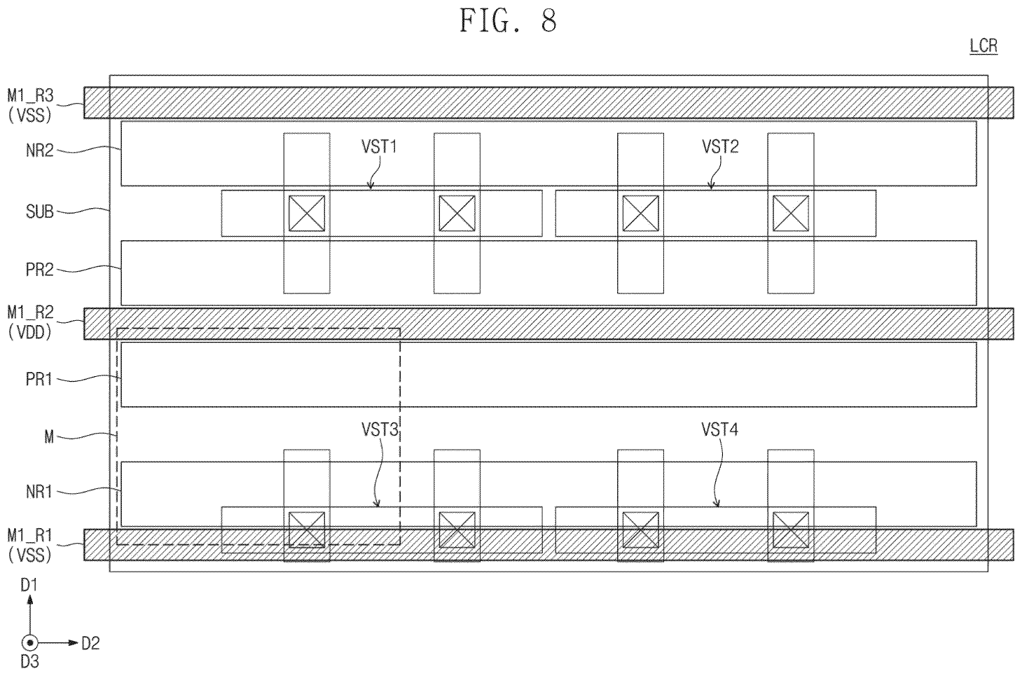

FIG. 8 is a diagram illustrating a logic cell region according to an embodiment of the disclosure. FIG. 8 illustrates an example of a logic cell region LCR.

In detail, a plurality of power lines M1_R1, M1_R2, and M1_R3 may be provided on the substrate SUB. The power lines M1_R1, M1_R2, and M1_R3 may be arranged in the first direction D1. The power lines M1_R1, M1_R2, and M1_R3 may extend in the second direction D2. In an embodiment, the power lines M1_R1, M1_R2, and M1_R3 may include the first, second, and third power lines M1_R1, M1_R2, and M1_R3.

In an embodiment, the first and third power lines M1_R1 and M1_R3 may be used as paths, to which a source voltage VSS (e.g., a ground voltage) is applied. The second power line M1_R2 may be a path, to which a drain voltage VDD (e.g., a power voltage) is applied.

A first n-type metal-oxide-semiconductor (MOS) field-effect transistor (FET) (NMOSFET) region NR1 may be provided to be adjacent to the first power line M1_R1. First and second p-type MOSFET (PMOSFET) regions PR1 and PR2 may be respectively provided to be adjacent to both sides of the second power line M1_R2. A second NMOSFET region NR2 may be provided to be adjacent to the third power line M1_R3. The first and second NMOSFET regions NR1 and NR2 and the first and second PMOSFET regions PR1 and PR2 may extend along the power lines M1_R1, M1_R2, and M1_R3 and in the second direction D2.

The logic cell region LCR according to example embodiments may be a single driver cell. The driver cell may be provided to occupy a chip area that is larger than other logic cells. A current of a signal, which is input to or output from the driver cell, may be larger than those in other logic cells.

The vertical structures VST1-VST4 described above may be provided on the logic cell region LCR. For example, the first and second vertical structures VST1 and VST2 may be provided to be in parallel with each other. The first and second vertical structures VST1 and VST2 may be substantially the same as those described with reference to FIGS. 5 and 7. As an example, the first and second vertical structures VST1 and VST2 may be used to transmit signals, which are provided from or to the driver cell.

The third and fourth vertical structures VST3 and VST4 may be provided to be in parallel with each other. The third and fourth vertical structures VST3 and VST4 may also be substantially the same as those described with reference to FIGS. 5 and 7. As an example, the third and fourth vertical structures VST3 and VST4 may be used to deliver an electric power, which is supplied from or to the driver cell.

The vertical structure VST previously described with reference to FIGS. 5 and 7 may allow signals or electric power to be conducted through separate current paths (e.g., through respective interconnection lines in the n-th and (n−2)-th metal layers Mn and Mn−2). Accordingly, for a relatively large amount of current in a largest driver cell, the semiconductor devices disclosed herein may realize an efficiently-distributed current flow.

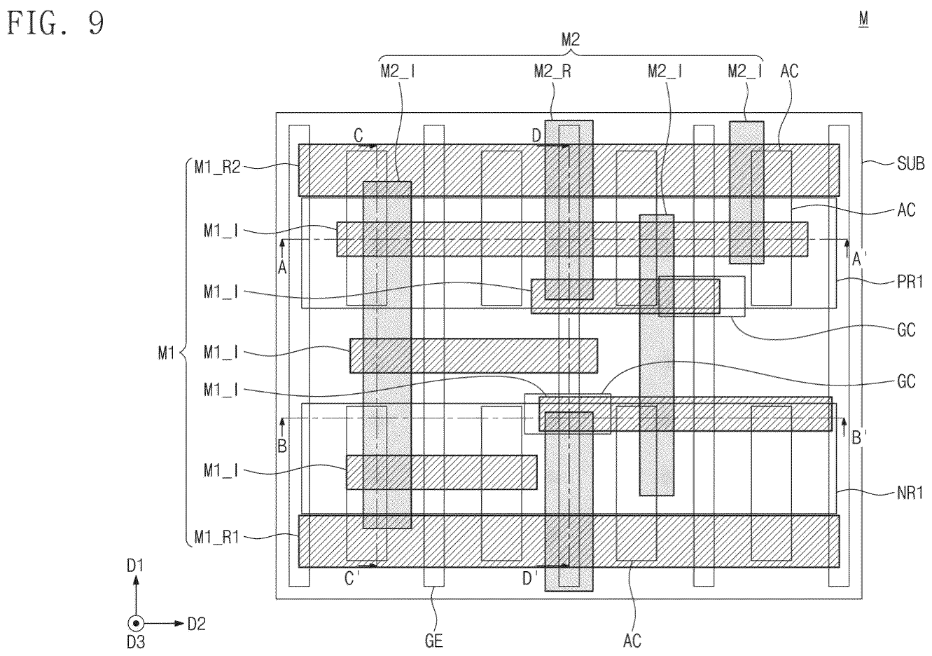

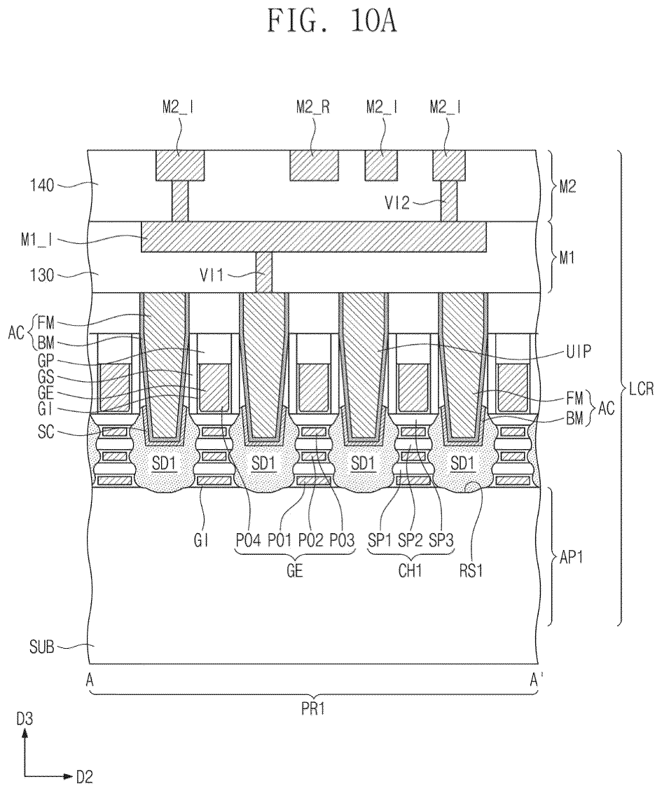

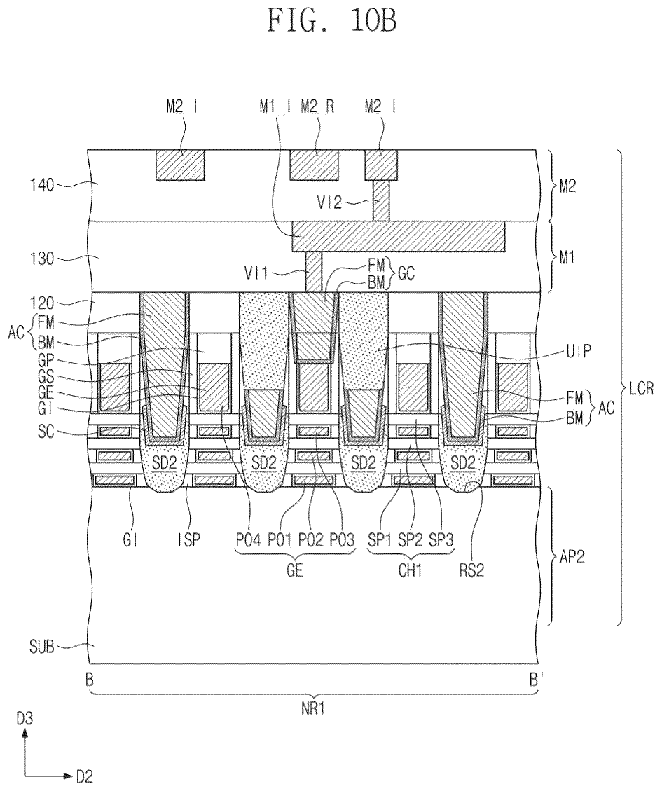

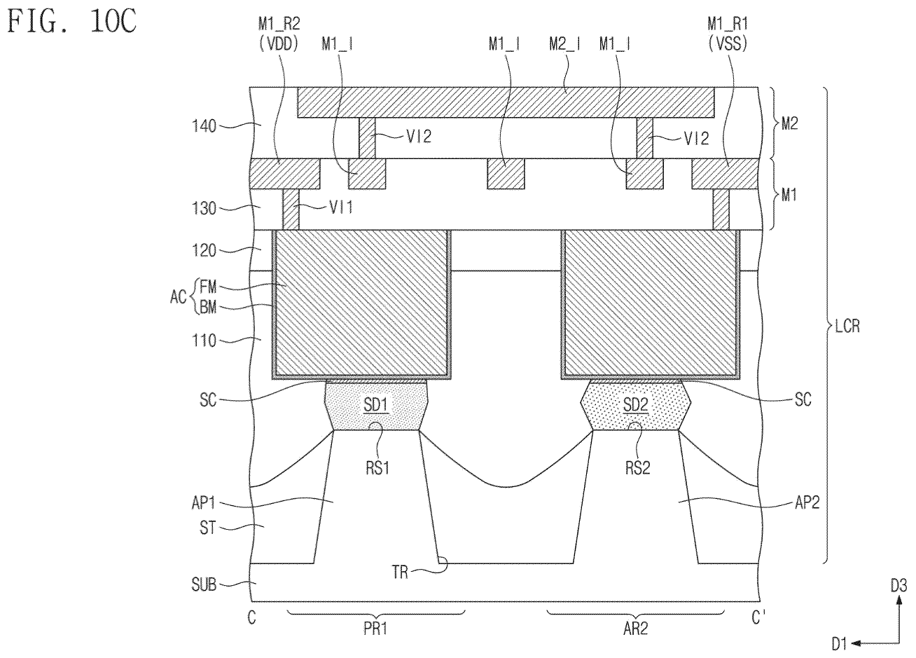

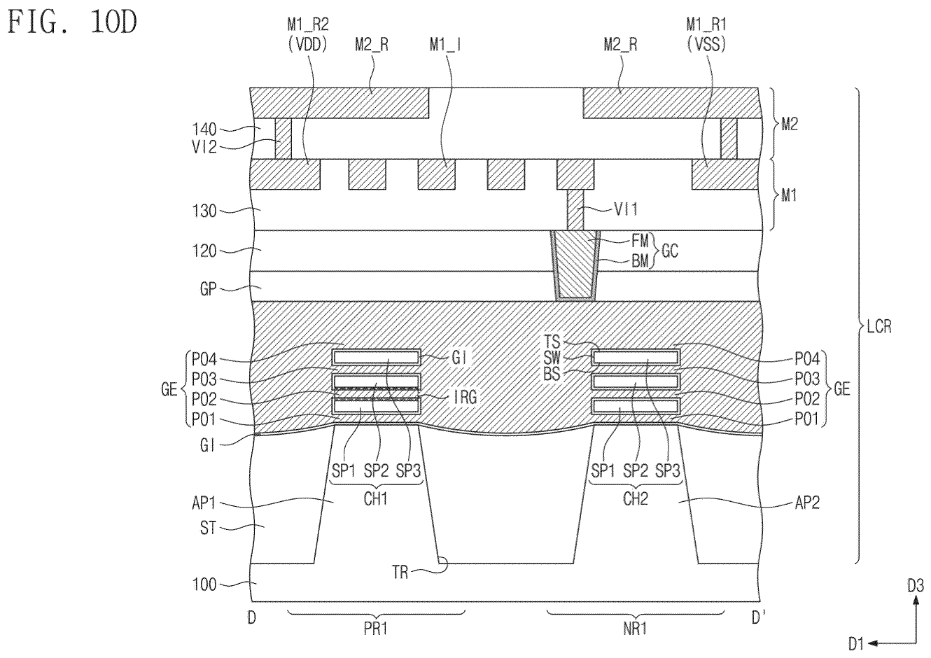

FIG. 9 is a diagram illustrating a portion ‘M’ of FIG. 8 according to an embodiment of the disclosure. FIGS. 10A, 10B, 10C and 10D are cross-sectional views, which are respectively taken along lines A-A′, B-B′, C-C′, and D-D′ of FIG. 9, according to an embodiment of the disclosure. The semiconductor device shown in FIGS. 9 and 10A to 10D may illustrate an example of a portion of the logic cell region LCR.

Referring to FIGS. 9 and 10A to 10D, the substrate SUB may include the first PMOSFET region PR1 and the first NMOSFET region NR1. The first PMOSFET region PR1 and the first NMOSFET region NR1 may extend in the second direction D2.

A first active pattern AP1 and a second active pattern AP2 may be defined by a trench TR, which is formed in an upper portion of the substrate SUB. The first active pattern AP1 may be provided on the first PMOSFET region PR1, and the second active pattern AP2 may be provided on the first NMOSFET region NR1. The first and second active patterns AP1 and AP2 may extend in the second direction D2. The first and second active patterns AP1 and AP2 may be vertically-protruding portions of the substrate SUB (e.g., see FIGS. 10C and 10D).

A device isolation layer ST may be provided on the substrate SUB. The device isolation layer ST may be provided to fill the trench TR. The device isolation layer ST may include a silicon oxide layer. The device isolation layer ST may not cover (or at least only partially cover) first and second channel patterns CH1 and CH2 to be described below.

A first channel pattern CH1 may be provided on the first active pattern AP1. A second channel pattern CH2 may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (i.e., the third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon (more specifically, single crystalline silicon). In an embodiment, the first to third semiconductor patterns SP1, SP2, and SP3 may be a stack of nano sheets.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. In other words, each pair of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between each pair of the second source/drain patterns SD2. In other words, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an embodiment, each of the first and second source/drain patterns SD1 and SD2 may have a top surface that is higher than a top surface of the third semiconductor pattern SP3. In an embodiment, a top surface of at least one of the first and second source/drain patterns SD1 and SD2 may be located at substantially the same level as the top surface of the third semiconductor pattern SP3.

In an embodiment, the first source/drain patterns SD1 may include a semiconductor material (e.g., SiGe) whose lattice constant is larger than a lattice constant of a semiconductor material (e.g., Si) of the substrate SUB. In this case, the pair of the first source/drain patterns SD1 may exert a compressive stress on the first channel patterns CH1 therebetween. In an embodiment, the second source/drain patterns SD2 may be formed of or include the same semiconductor material (e.g., Si) as the substrate SUB.

In an embodiment, a side surface of the first source/drain pattern SD1 may have an uneven or embossing shape. For example, the side surface of the first source/drain pattern SD1 may have a wavy profile. The side surface of the first source/drain pattern SD1 may be protruded toward first to third inner electrodes PO1, PO2, and PO3 of a gate electrode GE, which will be described below.

Gate electrodes GE may be provided on the first and second channel patterns CH1 and CH2. Each of the gate electrodes GE may extend in the first direction D1 to cross the first and second channel patterns CH1 and CH2. Each of the gate electrodes GE may vertically overlap the first and second channel patterns CH1 and CH2. The gate electrodes GE may be arranged at a first pitch in the second direction D2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 10D, the gate electrode GE may be provided on a top surface TS, a bottom surface BS, and opposite side surfaces SW of each of the first to third semiconductor patterns SP1, SP2, and SP3. That is, the transistor according to the present embodiment may be a three-dimensional field effect transistor (e.g., a multi-bridge channel FET (MBCFET) or gate-all-around FET (GAAFET)) in which the gate electrode GE is provided to three-dimensionally surround the channel pattern.

Referring to FIG. 10B, on the first NMOSFET region NR1, inner spacers ISP may be respectively interposed between the first to third inner electrodes PO1, PO2, and PO3 of the gate electrode GE and the second source/drain pattern SD2. Each of the first to third inner electrodes PO1, PO2, and PO3 of the gate electrode GE may be spaced apart from the second source/drain pattern SD2 with the inner spacer ISP interposed therebetween. The inner spacer ISP may prevent a leakage current from the gate electrode GE.

Referring back to FIGS. 9 and 10A to 10D, a pair of gate spacers GS may be respectively disposed on opposite side surfaces of the outer electrode PO4 of the gate electrode GE. The gate spacers GS may extend along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described below. In an embodiment, the gate spacers GS may be formed of or include at least one of SiCN, SiCON, and SiN. In an embodiment, the gate spacers GS may have a multi-layered structure, which is formed of or includes at least two different materials from SiCN, SiCON, and SiN.

A gate capping pattern GP may be provided on the gate electrode GE. The gate capping pattern GP may extend along the gate electrode GE or in the first direction D1. The gate capping pattern GP may be formed of or include a material having an etch selectivity with respect to first and second interlayer insulating layers 110 and 120, which will be described below. For example, the gate capping pattern GP may be formed of or include at least one of SiON, SiCN, SiCON, and SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and the opposite side surfaces SW of each of the first to third semiconductor patterns SP1, SP2, and SP3. The gate insulating layer GI may cover a top surface of the device isolation layer ST below the gate electrode GE.

In an embodiment, the gate insulating layer GI may be formed of or include at least one of silicon oxide, silicon oxynitride, and high-k dielectric materials. For example, the gate insulating layer GI may have a structure, in which a silicon oxide layer and a high-k dielectric layer are stacked. The high-k dielectric layer may be formed of or include a high-k dielectric material whose dielectric constant is higher than that of silicon oxide. As an example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In an embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The gate electrode GE may include a first metal pattern and a second metal pattern on the first metal pattern. The first metal pattern may be provided on the gate insulating layer GI and may be adjacent to the first to third semiconductor patterns SP1, SP2, and SP3. The first metal pattern may include a work-function metal, which may be used to adjust a threshold voltage of the transistor. By adjusting a thickness and composition of the first metal pattern, the semiconductor devices disclosed herein may realize a transistor having a desired threshold voltage. For example, the first to third inner electrodes PO1, PO2, and PO3 of the gate electrode GE may be composed of the first metal pattern including the work-function metal.

The first metal pattern may include a metal nitride layer. For example, the first metal pattern may include a layer that is composed of at least one metallic material, including titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include at least one metallic material, including tungsten (W), aluminum (Al), titanium (Ti), and tantalum (Ta). In an embodiment, the outer electrode PO4 of the gate electrode GE may include the first metal pattern and the second metal pattern on the first metal pattern.

A first interlayer insulating layer 110 may be provided on the substrate SUB. The first interlayer insulating layer 110 may cover the gate spacers GS and the first and second source/drain patterns SD1 and SD2. The first interlayer insulating layer 110 may have a top surface that is substantially coplanar with the top surface of the gate capping pattern GP and the top surface of the gate spacer GS. A second interlayer insulating layer 120 may be formed on the first interlayer insulating layer 110 to cover the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110 to 140 may include a silicon oxide layer.

Active contacts AC may be provided to penetrate the first and second interlayer insulating layers 110 and 120 and may be electrically connected to the first and second source/drain patterns SD1 and SD2, respectively. A pair of the active contacts AC may be respectively provided at both sides of the gate electrode GE. When viewed in a plan view, the active contact AC may be a bar-shaped pattern that extends in the first direction D1.

The active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. The active contact AC may cover (or at least partially cover) a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, and cobalt silicide.

Gate contacts GC may penetrate the second interlayer insulating layer 120 and the gate capping pattern GP and to be electrically connected to the gate electrodes GE, respectively. When viewed in a plan view, the gate contacts GC may overlap the first PMOSFET and NMOSFET regions PR1 and NR1, respectively. As an example, the gate contact GC may be provided on the second active pattern AP2 (e.g., see FIG. 10B).

In an embodiment, referring to FIG. 10B, a region, which is located on the active contact AC and adjacent to the gate contact GC, may be filled with an upper insulating pattern UIP. A bottom surface of the upper insulating pattern UIP may be lower than a bottom surface of the gate contact GC. In other words, a top surface of the active contact AC adjacent to the gate contact GC may be formed at a level, which is lower than the bottom surface of the gate contact GC, by the upper insulating pattern UIP. Accordingly, the semiconductor devices disclosed herein may prevent the gate contact GC and the active contact AC, which are adjacent to each other, from being in contact with each other and thereby to prevent a short circuit issue from occurring therebetween.

Each of the active and gate contacts AC and GC may include a conductive pattern FM and a barrier pattern BM enclosing the conductive pattern FM. For example, the conductive pattern FM may be formed of or include at least one of metallic materials, such as aluminum, copper, tungsten, molybdenum, and cobalt. The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CoN), and platinum nitride (PtN).

A first metal layer M1 may be provided in the third interlayer insulating layer 130. For example, the first metal layer M1 may include the first power line M1_R1, the second power line M1_R2, and first signal lines M1_I. The interconnection lines M1_R1, M1_R2, and M1_I of the first metal layer M1 may extend in the second direction D2 to be parallel to each other.

The first signal lines M1_I of the first metal layer M1 may be disposed between the first and second power lines M1_R1 and M1_R2. The first signal lines M1_I of the first metal layer M1 may be arranged at a second pitch in the first direction D1. The second pitch may be smaller than the first pitch. A linewidth of each of the first signal lines M1_I may be smaller than a linewidth of each of the first and second power lines M1_R1 and M1_R2.

The first metal layer M1 may further include first vias VI1. The first vias VI1 may be respectively provided below the interconnection lines M1_R1, M1_R2, and M1_I of the first metal layer M1. The active contact AC and the interconnection line of the first metal layer M1 may be electrically connected through the first via VI1. The gate contact GC and the interconnection line of the first metal layer M1 may be electrically connected through the first via VI1.

The interconnection line of the first metal layer M1 and the first via VI1 thereunder may be formed by separate processes. For example, the interconnection line and the first via VI1 of the first metal layer M1 may be independently formed by respective single damascene processes. The semiconductor device according to example embodiments may be fabricated using a sub-20 nm process.

A second metal layer M2 may be provided in the fourth interlayer insulating layer 140. The second metal layer M2 may include second signal lines M2_I and second power delivery lines M2_R. Each of the interconnection lines M2_1 and M2_R of the second metal layer M2 may be a line-shaped pattern or bar-shaped pattern that extends in the first direction D1.

The second metal layer M2 may further include second vias VI2, which are respectively provided below the interconnection lines M2_I and M2_R. The interconnection lines of the first and second metal layers M1 and M2 may be electrically connected through the second via VI2. The interconnection line of the second metal layer M2 and the second via VI2 thereunder may be formed together by a dual damascene process.

The second signal line M2_1 may be electrically connected to the first signal line M1_I through the second via VI2 (e.g., see FIG. 10C). The second power delivery line M2_R may be electrically connected to one of the first and second power lines M1_R1 and M1_R2 through the second via VI2 (e.g., see FIG. 10D).

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials, such as e.g., aluminum, copper, tungsten, molybdenum, ruthenium, and cobalt.

The third metal layer M3, the fourth metal layer M4, the fifth metal layer M5, the sixth metal layer M6, . . . , the (n−2)-th metal layer Mn−2, the (n−1)-th metal layer Mn−1, the n-th metal layer Mn, and the largest metal layer HM, which are sequentially stacked, may be provided on the second metal layer M2.

In an embodiment, the vertical structure VST may be coupled to the second signal line M2_I illustrated in FIG. 10C. Thus, signals, which are generated in the logic cell region LCR, may be vertically transmitted to the largest metal layer HM through the vertical structure VST.

In another embodiment, the vertical structure VST may be coupled to the second power delivery line M2_R illustrated in FIG. 10D. Thus, an electric power, which is supplied through the largest metal layer HM, may be vertically delivered to the logic cell region LCR through the vertical structure VST or vice versa.

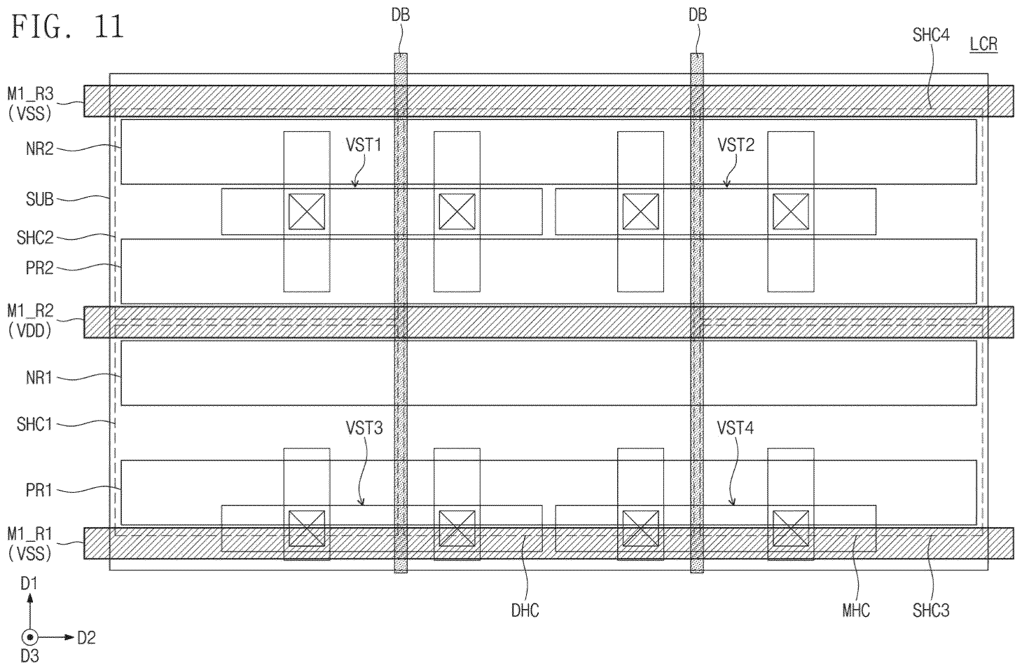

FIG. 11 is a diagram illustrating a logic cell region according to an embodiment of the disclosure. FIG. 11 illustrates another example of the logic cell region LCR.

The logic cell region LCR according to example embodiments may include a plurality of logic cells, which are two-dimensionally arranged. For example, a first single height cell SHC1, a second single height cell SHC2, a third single height cell SHC3, a fourth single height cell SHC4, and a double height cell DHC may be two-dimensionally disposed in the logic cell region LCR.

The first single height cell SHC1 and the third single height cell SHC3 may be disposed between the first and second power lines M1_R1 and M1_R2. The second single height cell SHC2 and the fourth single height cell SHC4 may be disposed between the second and third power lines M1_R2 and M1_R3. The second single height cell SHC2 may be adjacent to the first single height cell SHC1 in the first direction D1. The fourth single height cell SHC4 may be adjacent to the third single height cell SHC3 in the first direction D1.

The double height cell DHC may be disposed between the first and third power lines M1_R1 and M1_R3. The double height cell DHC may be interposed between the first and third single height cell SHC1 and SHC3 and between the second and fourth single height cell SHC2 and SHC4.

A division structure DB may be provided between the first and second single height cells SHC1 and SHC2 and the double height cell DHC. The division structure DB may be provided between the third and fourth single height cells SHC3 and SHC4 and the double height cell DHC. The active regions of the logic cells may be electrically disconnected from each other by the division structure DB.

The logic cell region LCR according to example embodiments may be a region, in which a plurality of logic cells are arranged, unlike the driver cell described with reference to FIG. 8. The first to fourth vertical structures VST1-VST4 described above may also be provided on the logic cell region LCR according to the present embodiment. For example, the first vertical structure VST1 may be used as a routing line connecting the second single height cell SHC2 to the double height cell DHC and may also be used to transmit signals in a vertical direction. The second vertical structure VST2 may be used as a routing line connecting the fourth single height cell SHC4 to the double height cell DHC and may also be used to transmit signals in the vertical direction.

According to an embodiment of the disclosure, a vertical structure, which is used to vertically deliver signals and/or power of a logic cell region, may be configured to deliver a current to a largest metal layer in a dispersed manner. For example, the vertical structure may be configured to prevent the flow of the current from being concentrated to a specific interconnection line. Accordingly, the semiconductor devices disclosed herein may improve electrical and reliability characteristics of the semiconductor device. In the case where the vertical structure is applied to a cell (e.g., a largest driver cell) requiring a relatively large amount of current, driving stability of the semiconductor device may be improved.

Each of the embodiments provided in the above description is not excluded from being associated with one or more features of another example or another embodiment also provided herein or not provided herein but consistent with the disclosure.

While example embodiments of the disclosure have been particularly shown and described, it will be understood by one of ordinary skill in the art that variations in form and detail may be made therein without departing from the spirit and scope of the attached claims.

What is claimed is:

1. A semiconductor device, comprising:
a logic cell region on a substrate;
an interconnection layer on the logic cell region, the interconnection layer comprising a plurality of metal layers on the logic cell region; and
a first vertical structure in the interconnection layer,
wherein the first vertical structure vertically connects the logic cell region to an uppermost metal layer of the plurality of metal layers,
wherein the first vertical structure comprises a plurality of unit structures, the plurality of unit structures overlapping each other,
wherein each of the plurality of unit structures comprises a lower via, a lower interconnection line, an upper via, and an upper interconnection line,
wherein the lower interconnection line and the upper interconnection line of each respective unit structure of the plurality of unit structures cross each other,
wherein the upper interconnection line of each of the plurality of unit structures comprises a first upper interconnection line, and
wherein the upper interconnection line for each of the plurality of unit structures except for an uppermost unit structure of the plurality of unit structures comprises a second upper interconnection line adjacent to the first upper interconnection line.

2. The semiconductor device of claim 1, wherein the interconnection layer further comprises a connection via on the uppermost metal layer of the plurality of metal layers and a large interconnection line on the connection via, the large interconnection line being a largest interconnection line among interconnection lines of the semiconductor device, and
wherein the first upper interconnection line of the uppermost unit structure of the plurality of unit structures vertically overlaps the connection via.

3. The semiconductor device of claim 1, wherein the first upper interconnection lines of the plurality of unit structures vertically overlap each other, and
wherein the second upper interconnection lines of the plurality of unit structures are vertically overlap each other.

4. The semiconductor device of claim 1, further comprising a second vertical structure adjacent to the first vertical structure,
wherein the uppermost metal layer of the plurality of metal layers comprises a connection line connected to the first vertical structure and the second vertical structure,
wherein the interconnection layer further comprises a large interconnection line on the connection line and a connection via between the connection line and the large interconnection line, the large interconnection line being a largest interconnection line among interconnection lines of the semiconductor device,
wherein a first current delivered through the first vertical structure is directly conducted to the connection via, and
wherein a second current delivered through the second vertical structure is conducted to the connection via through the connection line.

5. The semiconductor device of claim 1, further comprising a second vertical structure adjacent to the first vertical structure,
wherein the uppermost metal layer of the plurality of metal layers comprises a connection line connected to the first vertical structure and the second vertical structure,
wherein the interconnection layer further comprises a large metal layer on the uppermost metal layer of the plurality of metal layers, the large metal layer being a largest metal among the plurality of metal layers,
wherein the first vertical structure is configured to provide a first current path and a second current path, which are vertically extended from the logic cell region,
wherein the second vertical structure is configured to provide a third current path and a fourth current path, which are vertically extended from the logic cell region,
wherein the first current path and the second current path are merged in the lower interconnection line of the uppermost unit structure of the plurality of unit structures, forming a first merged current path connected to the large metal layer, and
wherein the third current path and the fourth current path are merged in the connection line, forming a second merged current path connected to the large metal layer.

6. The semiconductor device of claim 1, wherein the logic cell region comprises:
a first active pattern and a second active pattern formed in an upper portion of the substrate and spaced apart from each other in a first direction;
a first channel pattern and a first source/drain pattern on the first active pattern;
a second channel pattern and a second source/drain pattern on the second active pattern;
a gate electrode on the first channel pattern and the second channel pattern;
an interlayer insulating layer provided on the first source/drain pattern, the second source/drain pattern and the gate electrode;
an active contact penetrating the interlayer insulating layer and connected to at least one of the first source/drain pattern and the second source/drain pattern;
a gate contact penetrating the interlayer insulating layer and connected to the gate electrode; and
an interconnection line on the interlayer insulating layer,
wherein the interconnection line is connected to at least one of the active contact and the gate contact, and
wherein the first vertical structure is provided to electrically connect the interconnection line to the uppermost metal layer of the plurality of metal layers.

7. The semiconductor device of claim 1, wherein the first vertical structure is configured to provide a roundabout path to a current transmitted through the first vertical structure.

8. The semiconductor device of claim 1, wherein the first vertical structure is configured to deliver a signal or power to the logic cell region.

9. The semiconductor device of claim 1, wherein the logic cell region is a driver cell.

10. The semiconductor device of claim 1, wherein the logic cell region comprises a plurality of logic cells, which are two-dimensionally disposed.

11. A semiconductor device, comprising:
a logic cell region on a substrate;
an interconnection layer on the logic cell region, the interconnection layer comprising a plurality of metal layers on the logic cell region; and
a first vertical structure and a second vertical structure in the interconnection layer,
wherein the first vertical structure and the second vertical structure vertically connect the logic cell region to an n-th metal layer in an uppermost metal layer of the plurality of metal layers, where n is an from 9 to 15,
wherein each of the first vertical structure and the second vertical structure comprises alternately stacked lower interconnection lines and upper interconnection lines,
wherein the lower interconnection lines and the upper interconnection lines of each respective vertical structure cross each other, and
wherein the first vertical structure further comprises at least one layer between the logic cell region and the n-th metal layer, electrically connecting the logic cell region and the n-th metal layer.

12. The semiconductor device of claim 11, wherein the at least one layer of the first vertical structure is in an (n−1)-th metal layer.

13. The semiconductor device of claim 11, wherein the lower interconnection lines and the upper interconnection lines vertically overlap.

14. The semiconductor device of claim 11, wherein the n-th metal layer comprises a connection line connected to the first vertical structure and the second vertical structure,
wherein the interconnection layer further comprises a large interconnection line on the connection line and a connection via between the connection line and the large interconnection line, the large interconnection line being a largest interconnection line among interconnection lines of the semiconductor device,
wherein a first current delivered through the first vertical structure is directly conducted to the connection via, and
wherein a second current delivered through the second vertical structure is conducted to the connection via through the connection line.

15. The semiconductor device of claim 11, wherein the first vertical structure and the second vertical structure are configured to deliver a signal or power to the logic cell region.

16. A semiconductor device, comprising:
a logic cell region on a substrate;
an interconnection layer on the logic cell region, the interconnection layer comprising a plurality of metal layers on the logic cell region and a large metal layer on an n-th metal layer, wherein the large metal layer being a largest metal layer among the plurality of metal layers and wherein the large metal layer is an uppermost metal layer of the plurality of metal layers; and
a first vertical structure and a second vertical structure in the interconnection layer,
wherein the first vertical structure and the second vertical structure vertically connect the logic cell region and the large metal layer,
wherein the first vertical structure is configured to provide a first current path and a second current path which vertically extend from the logic cell region,
wherein the second vertical structure is configured to provide a third current path and a fourth current path which vertically extend from the logic cell region,
wherein the first current path and the second current path are merged in an interconnection line of an (n−2)-th metal layer, forming a first merged current path connected to the largest metal layer,
wherein the third current path and the fourth current path are merged in an interconnection line of the n-th metal layer, forming a second merged current path connected to the largest metal layer, and
wherein n is an integer from 9 to 15.

17. The semiconductor device of claim 16, wherein the first vertical structure comprises a first upper interconnection line in an (n−1)-th metal layer,
wherein the second vertical structure comprises a second upper interconnection line and a third upper interconnection line disposed in the (n−1)-th metal layer,
wherein the first upper interconnection line is used for both of the first current path and the second current path,
wherein the second upper interconnection line is used for the third current path, and
wherein the third upper interconnection line is used for the fourth current path.

18. The semiconductor device of claim 16, wherein the each of the first current path, the second current path, the third current path, and the fourth current path comprises alternately stacked lower interconnection lines and upper interconnection lines, and
wherein the lower interconnection lines and the upper interconnection lines of each respective current path cross each other.

19. The semiconductor device of claim 18, wherein the lower interconnection lines and the upper interconnection lines of each respective current path vertically overlap.

20. The semiconductor device of claim 16, wherein the n-th metal layer comprises a connection line connected to the first vertical structure and the second vertical structure,
wherein the large metal layer comprises a connection via on the connection line and a large interconnection line on the connection via, the large interconnection line being a largest interconnection line among interconnection lines of the semiconductor device,
wherein the first merged current path is directly connected to the connection via, and
wherein the third current path and the fourth current path are connected to the connection via through the connection line.
